(19) United States
(12) Patent Application Publication
(10) Pub. No.: US 2026/0201606 A1
(43) Pub. Date: Jul. 16, 2026

(54) NEGATIVE ACTIVE MATERIAL, LITHIUM SECONDARY BATTERY CONTAINING THE SAME, AND METHOD FOR MANUFACTURING THE NEGATIVE ACTIVE MATERIAL

(71) Applicant: EBS SQUARE, Inc., Seongnam-si (KR)

(72) Inventors: Sung Won HWANG, Hwaseong-si (KR); Min Kyoung NA, Seoul (KR); Hyun Hee JUNG, Seoul (KR)

(73) Assignee: EBS SQUARE, Inc., Seongnam-si (KR)

(21) Appl. No.: 19/367,112

(22) Filed: Oct. 23, 2025

(30) Foreign Application Priority Data
Jan. 16, 2025 (KR) 10-2025-0006603
Sep. 24, 2025 (KR) 10-2025-0137714

(51) Int. Cl. C30B 29/10; C30B 25/00; C30B 33/00; H01M 10/052

(52) U.S. Cl. CPC C30B 29/10; C30B 25/00; C30B 33/00; H01M 10/052

(57) ABSTRACT

A negative active material according to an embodiment may include a composite including a silicon-based active material, topological material nanoparticles, and a carbon nanoribbon.

### CROSS-REFERENCE TO RELATED APPLICATION(S)

This application claims benefit of priority to Korean Patent Application No. 10-2025-0006603 filed on Jan. 16, 2025 and No. 10-2025-0137714 filed on Sep. 24, 2025 in the Korean Intellectual Property Office, the disclosure of which is incorporated herein by reference in its entirety.

### BACKGROUND

### 1. Field

The present disclosure relates to a negative active material including a silicon-based active material and having improved electric capacity, electrochemical properties, structural stability, and electrical conductivity, a lithium secondary battery containing the same, and a method for manufacturing the negative active material.

### 2. Description of Related Art

Recently, due to the rapid growth of electric vehicle, energy storage system (ESS), and mobile device markets, a demand for lithium secondary batteries with high energy density, high output, and long lifespan characteristics has increased. Conventional lithium secondary batteries have already achieved a certain level or more of performance in terms of energy density, lifespan, and stability, but an energy density of 1,000 Wh/L or more is required in high-performance applications such as electric vehicles. Accordingly, an increase in the capacity of a negative active material, which is a core component of the lithium secondary batteries, has emerged as an important technical challenge.

Graphite, which is a commercially available negative electrode material for lithium secondary batteries, has a stable structure and long lifespan characteristics, but has a theoretical capacity of only about 374 mAh/g, and thus, has limitations in in realizing a high-energy-density cell. For this reason, research into a high-capacity negative electrode material such as silicon (Si) and silicon oxide (SiOₓ) has been actively conducted. Silicon has a very high theoretical capacity of 3,579 mAh/g, and SiOₓ exhibits a lower expansion rate and more excellent cycle characteristics than silicon. Accordingly, silicon and SiOₓ have attracted attention as next-generation negative electrode material candidates.

However, a silicon-based negative electrode material undergoes volume expansion of 300% or more during charge and discharge, resulting in structural and electrochemical instability such as particle fragmentation, electrode separation, and repeated formation of a solid electrolyte interphase (SEI) layer. In particular, SiOX forms irreversible by-products such as Li₂O and LiₓSiO_{γ} during a lithiation process, thereby causing a decrease in initial efficiency and lithium loss. This instability leads to a rapid capacity reduction and a cycle life reduction. In addition, due to low electrical conductivity, it is difficult to achieve high-speed charge and discharge characteristics, and it is essential to make a conductive material composite in order to secure an electron transport path.

In order to solve these problems, a design of a composite structure capable of controlling the volume expansion of a silicon-based active material, improving electrical conductivity, and ensuring structural stability has emerged as an important technical challenge. In particular, graphene-based carbon materials are known to be effective in suppressing the expansion of silicon-based particles and stabilizing the SEI, owing to their excellent conductivity and mechanical strength.

### SUMMARY

An aspect of the present disclosure provides a negative active material that includes a silicon-based active material composite including a silicon-based active material, topological material nanoparticles, and a carbon nanoribbon.

A negative active material according to an embodiment includes a composite including a silicon-based active material, topological material nanoparticles, and a carbon nanoribbon.

The composite includes a core including the silicon-based active material and the topological material nanoparticles, and a shell surrounding at least a portion of the core and including the carbon nanoribbon.

The topological material nanoparticles include at least one of BiSe and BiTe.

The topological material nanoparticles have an average particle diameter of 5 nm to 50 nm.

The silicon-based active material includes at least one of Si and SiOₓ (0<x≤2).

The silicon-based active material has an average particle diameter of 50 nm to 5 μm.

The silicon-based active material has a single-crystal structure.

The shell has a thickness of 5 nm to 50 nm.

The composite has a porous structure.

The composite has an average particle diameter of 50 nm to 5 μm.

A lithium secondary battery according to another embodiment includes a negative electrode including the negative active material; a positive electrode including a positive active material; and an electrolyte transferring lithium ions to the positive electrode and the negative electrode.

The lithium secondary battery exhibits a capacity retention of 98% or more after 2,000 or more charge and discharge cycles at 0.1 C.

The lithium secondary battery exhibits a capacity of 1,950 mAh/g or more after 2,000 or more charge and discharge cycles at a current density of 1 A/g.

A method for manufacturing a negative active material according to another embodiment includes a pretreating step of treating a silicon-based precursor to manufacture porous silicon particles; and a composite manufacturing step of manufacturing a composite of a core-shell structure using the pretreated silicon-based particles, a topological material precursor, and a carbon nanoribbon precursor.

The pretreating step includes: melting a silicon-based precursor and the topological material precursor; and condensing a porous composite, and the composite manufacturing step includes: annealing the pretreated particles; and forming a carbon nanoribbon shell outside the annealed particles.

### BRIEF DESCRIPTION OF THE DRAWINGS

FIG. 1 is a schematic cross-sectional view of a composite including a silicon-based active material and a carbon nanoribbon according to an embodiment of the present disclosure.

FIG. 2 is a field emission scanning electron microscope (FE-SEM) image showing a negative active material including a composite manufactured according to an embodiment of the present disclosure.

FIG. 3 is an FE-SEM image showing a negative active material including the composite manufactured according to an embodiment of the present disclosure.

FIG. 4 is a high-resolution transmission electron microscope (HR-TEM) image showing a negative active material including the composite manufactured according to an embodiment of the present disclosure.

FIGS. 5a and 5b are graphs showing the results of X-ray photoelectron spectroscopy (XPS) for analyzing a surface chemical composition of the composite according to an embodiment of the present disclosure.

FIG. 6 shows the results of an X-ray diffraction (XRD) pattern for analyzing a crystal structure of the composite according to an embodiment of the present disclosure.

FIG. 7 shows the results of Raman spectroscopy analysis for confirming the structural characteristics of the composite according to an embodiment of the present disclosure.

FIG. 8a shows the charge and discharge curves of a battery using the composite according to an embodiment of the present disclosure, and FIG. 8b shows the results of cyclic voltammetry (CV) analysis of a battery using the composite according to an embodiment of the present disclosure.

FIG. 9a shows the rate capability of a battery using the composite according to an embodiment of the present disclosure, and FIG. 9b shows the cycle life and coulombic efficiency of a battery using the composite according to an embodiment of the present disclosure, respectively.

### DETAILED DESCRIPTION

Throughout the present specification, like reference numerals refer to like components. It should be noted that the present specification does not describe all elements of the embodiments, and general contents in the art to which the present disclosure pertains, or repetitive descriptions among the embodiments, are omitted.

Throughout the present specification, when a certain portion is “connected” to another portion, it should be understood that this includes not only a direct connection but also an indirect connection, such as a connection via a wireless communication network.

Furthermore, when a certain portion “includes” a specific component, it should be understood that this does not exclude the presence of other components, and the portion may further include other components, unless explicitly stated otherwise.

A singular expression includes the corresponding plural forms, unless the context clearly indicates otherwise.

In addition, the terms such as “~unit,” “~er/or,” “~block,” “~member,” and “~module” may refer to a unit that processes at least one function or operation. For example, the above terms may refer to at least one hardware such as a field-programmable gate array (FPGA) or an application-specific integrated circuit (ASIC), at least one software stored in a memory, or at least one process executed by a processor.

Reference numerals assigned to respective steps are used for identifying the steps, and do not indicate the order of the steps. Unless the context clearly specifies a particular order, the steps may be carried out in an order different from that described.

Hereinafter, embodiments of a solid electrolyte according to an aspect and a secondary battery containing the same will be described in detail with reference to the accompanying drawings. The embodiments described herein and the configurations illustrated in the drawings are merely exemplary of the most preferred embodiment of the present disclosure, and various equivalents or modifications may be substituted for them at the time of filling this application.

### <Negative Active Material>

A negative active material is a compound capable of reversibly intercalating and deintercalating lithium ions.

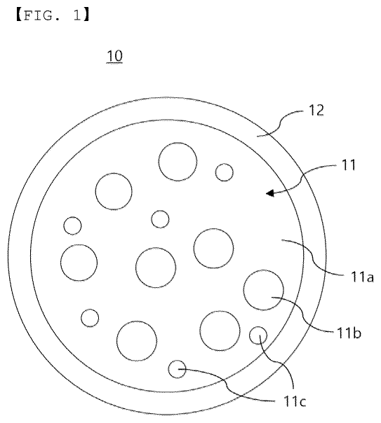

FIG. 1 is a schematic cross-sectional view of a composite including a silicon-based active material and a carbon nanoribbon according to an embodiment of the present disclosure.

Referring to FIG. 1, the negative active material includes a composite including a silicon-based active material, topological material nanoparticles, and a carbon nanoribbon. The composite 10 may have a core-shell structure.

Specifically, the composite 10 may include a core 11 including a silicon-based active material 11a and topological material nanoparticles 11b, and a shell 12 surrounding the core 11 and including a carbon nanoribbon.

The core 11 is positioned at the center of the composite 10 and is capable of reversibly intercalating and deintercalating lithium ions. The core 11 may include the silicon-based active material 11a and the topological material nanoparticles 11b. The core 11 may have a porous structure including nanopores 11c having a size of 5 nm to 50 nm.

The core 11 may be designed as a composite structure in which the silicon-based active material 11a is combined with the topological material nanoparticles 11b, thereby buffering the mechanical expansion of silicon particles while simultaneously improving electrical conductivity and interfacial stability.

The silicon-based active material 11a may include at least one of Si and SiOₓ (0<x≤2), and may be provided as porous silicon particles. The silicon-based active material 11a may have an average particle size of 50 nm to 5 μm or less.

The topological material nanoparticles 11b may include at least one of bismuth selenide (BiSe) and bismuth telluride (BiTe). In particular, bismuth selenide (BiSe) may provide lithium storage active sites by itself and may perform lithium-ion storage functions together with the silicon-based active material, while preventing structural destruction of the silicon-based active material due to its high structural stability. The topological material nanoparticles 11b may have an average particle diameter of 5 nm to 50 nm or less.

Specifically, bismuth selenide (BiSe) is generally known as Bi₂Se₃ and may refer to Bi₂Se₃. Bi₂Se₃ forms a unit layer composed of five layers of “Se—Bi—Se—Bi—Se,” in which the unit layers are bonded to each other via van der Waals forces. Its electronic structure is characterized by spin-momentum locking, in which the spin orientation of electrons is locked to their momentum direction.

The shell 12 may be formed on an outer surface of the core 11 to surround the core 11, and may include a carbon nanoribbon. The shell 12 may be provided to surround all or a portion of the surface of the core 11. The shell 12 absorbs mechanical stress caused by volume expansion of the core 11 and provides an electrical conduction path, thereby serving to enhance the structural stability and electrochemical properties of the composite. The shell 12 may have a thickness of 5 nm to 50 nm or less, and preferably 10 nm or less, and thus may be configured to uniformly surround the core 11.

The carbon nanoribbon (CNR), which is a carbon-based one-dimensional structure formed in a ribbon shape along the longitudinal direction, has an average thickness on the nanometer (nm) scale, and may have a structure that maintains single-crystal crystallinity. Specifically, the carbon nanoribbon may have a ribbon-shaped nanostructure with a width of about 1 nm to 999 nm and a length of about 1 nm to 999 nm. The carbon nanoribbon may additionally secure structural flexibility of the ribbon shape while maintaining excellent electrical conductivity and mechanical strength. Therefore, when the carbon nanoribbon forms the composite together with a silicon-based active material and topological material nanoparticles, the carbon nanoribbon may contribute to the enhancement of electrochemical and mechanical properties.

This composite has a core-shell structure, and thus has advantages such as improved electrical conductivity, controlled volume expansion of the silicon-based active material, SEI stabilization, and improved structural stability through a uniform shell structure.

A silicon-based active material may be included in the composite 10 in a weight ratio of 50 to 90 relative to the total weight of the composite, and a nanoribbon may be included in the composite 10 in a weight ratio of 10 to 50 relative to the total weight of the composite.

TABLE 1

| Silicon-based | Nanoribbon | Key characteristics |
|---|---|---|
| material (wt %) | (wt %) | and use purpose |
| 90 | 10 | Aimed at high capacity, |
| | | expansion suppression effect |
| | | is low |
| 80 | 20 | Practical high capacity |
| | | (>2,500 mAh/g), |
| | | supplementation of |
| | | mechanical stability |
| 70 | 30 | Securing of balance between |
| | | cycle life and stability, |
| | | aimed at commercialization |
| 60 | 40 | High stability, advantageous |
| | | for fast charge and discharge |
| | | conditions |
| 50 | 50 | Low-expansion and high-stability |
| | | design, applied to all-solid- |
| | | state batteries and systems |
| | | requiring high stability |

As shown in Table 1, by adjusting the weight ratio of the silicon-based active material and the weight ratio of the nanoribbons, a balance between stability and capacity may be adjusted. Specifically, when the weight ratio of the silicon-based active material is higher than that of the nanoribbons, for example, when the weight ratio of the silicon-based active material is 90 wt % and the weight ratio of the nanoribbon is 10 wt %, high capacity may be achieved, but the expansion suppression effect is limited. On the other hand, when the weight ratio of the silicon-based active material is lower than that of the nanoribbons, for example, when the weight ratio of the silicon-based active material is 50 wt % and the weight ratio of the nanoribbon is 50 wt %, a low-expansion and high-stability design is possible.

### <Negative Electrode>

The negative electrode includes a current collector, and a negative electrode material layer formed on the current collector and including a negative active material, a conductive agent, a binder, etc. For example, the negative electrode of the present disclosure may be obtained by preparing a coating slurry by mixing a negative active material, a binder, a conductive agent, a thickener, and a solvent such as an organic solvent or water, applying the coating slurry onto the current collector, drying the solvent or water, and then press-molding to form a negative electrode material layer. The current collector may be made of, for example, copper.

The negative active material may be the negative active material described above, and may be included in an amount of 50 wt % to 95 wt %, preferably 85 wt %, based on 100 parts by weight of the negative electrode material layer.

The conductive agent may include a carbon-based material having excellent electrical conductivity, preferably carbon black. The conductive agent may be included in an amount of 1 wt % to 15 wt %, preferably 10 wt %, based on 100 parts by weight of the negative electrode material layer.

The binder is not particularly limited and may include, for example, styrene-butadiene copolymers; (meth)acrylic copolymers obtained by copolymerizing ethylenically unsaturated carboxylic acid esters, as methyl such (meth)acrylate, ethyl (meth)acrylate, butyl (meth)acrylate, (meth)acrylonitrile, and hydroxyethyl (meth)acrylate, with ethylenically unsaturated carboxylic acids, such as acrylic acid, methacrylic acid, itaconic acid, fumaric acid, and maleic acid; and polymer compounds such as polyvinylidene fluoride, polyethylene oxide, polyepichlorohydrin, polyphosphazene, polyacrylonitrile, polyimide, and polyamideimide.

The binder may be included in an amount of 0.1 wt % to 20 wt %, preferably 5 wt % in the negative electrode material layer. When the binder content is 0.1 wt % or more, favorable adhesion is obtained, and the destruction of the negative electrode caused by expansion and contraction during charge and discharge tends to be suppressed. Meanwhile, when the binder content is 20 wt % or less, an increase in electrode resistance tends to be suppressed.

### <Lithium Secondary Battery>

A lithium secondary battery according to the present disclosure includes a positive electrode, the negative electrode, and an electrolyte.

The lithium-ion secondary battery may be formed, for example, by arranging a positive electrode to face a negative electrode through a separator, and then injecting an electrolyte solution containing an electrolyte.

The positive electrode may be obtained in the same manner as the negative electrode, by forming a positive electrode material layer on the surface of the current collector. The positive electrode current collector may be made of, for example, aluminum.

The positive active material of the positive electrode material layer of the lithium secondary battery according to the present disclosure is a compound capable of reversibly intercalating and deintercalating lithium ions. Specifically, the positive active material may include a lithium metal oxide containing lithium and one or more metals, such as cobalt, manganese, nickel, or aluminum. Examples of the lithium metal oxide include lithium-manganese-based oxide lithium-cobalt-based oxide, lithium-nickel-based oxide, lithium-cobalt-nickel-based oxide, lithium-nickel-manganese-cobalt-based oxide, or lithium iron phosphate.

The electrolyte is not particularly limited and any known electrolyte may be used. For example, a non-aqueous lithium-ion secondary battery may be manufactured by using a solution in which an electrolyte is dissolved in an organic solvent as a liquid electrolyte. Examples of electrolytes include LiPF₆, LiClO₄, LiBF₄, LiClF₄, LiAsF₆, LiSbF₆, LiAlO₄, LiAlCl₄, LiN(CF₃SO₂)₂, LiN(C₂F₅SO₂)₂, LiC(CF₃SO₂)₃, LiCl, and LiI. As the organic solvent, any solvent capable of dissolving the electrolyte may be used. Examples thereof include propylene carbonate, ethylene carbonate, diethyl carbonate, ethyl methyl carbonate, vinyl carbonate, γ-butyrolactone, 1,2-dimethoxyethane, and 2-methyltetrahydrofuran.

On the other hand, the electrolyte is not limited to liquid electrolytes and may also be a solid electrolyte.

As a separator, a variety of known separators may be used. Specific examples include paper separators, polypropylene separators, polyethylene separators, and glass fiber separators.

However, when a solid electrolyte is used, the separator may not be included in the lithium secondary battery.

### EXAMPLE

### Manufacture of Negative Active Material

In this example, a composite-type negative active material including a silicon-based active material, topological material nanoparticles, and a carbon nanoribbon (CNR) was manufactured.

Tetraethyl orthosilicate (TEOS) and a BiSe precursor were used as precursors for the silicon-based active material. During this synthesis process, topological-structure-based silicon nanoparticles (Si NPs) were prepared by reacting Bi and Se with SiOₓ formed from TEOS. Specifically, Bi and Se were melted at a high temperature in the range of 850° C. to 900° C. and maintained for a predetermined period of time to induce crystallization of primary particles. Subsequently, a secondary vapor-phase reaction was performed using a chemical vapor deposition (CVD) process to form Bi₂Se₃ nanoparticles. Through this high-temperature solid-state reaction, single-crystalline or polycrystalline Bi₂Se₃ was grown, ensuring high precision in crystal growth. During the reaction, the molar ratio of Bi to Se was set at 2:3, but a Bi-rich ratio of 1.95:3 was also applied, if necessary, to enable defect control. Additionally, a rotary furnace could be used during a melting process to ensure homogeneity of mixing, and during a cooling process, the material was slowly cooled to 600° C. at a rate of 1 to 3° C./h or rapidly quenched after 600° C. to control the crystal size and structure. When the slow cooling rate is slowed, a crystal size is increased and impurities are reduced, such that structural quality may be improved. When Se is excessively added, Bi defects may be suppressed and n-type carrier density may be reduced, and electrical conductivity may increase due to the generation of Bi interstitials under a Bi-rich condition, thereby increasing. Through this process, the synthesized topological-structure-based silicon nanoparticles were condensed with SiOₓ formed from TEOS to form porous silicon-based microparticles. These microparticles were subsequently composited with carbon nanoribbons to finally form a CNR@Si/BiSe composite.

The obtained nanoparticles were annealed at 650° C. for 4 hours under a nitrogen atmosphere, then dispersed in an ethanol solution and stirred at room temperature for 8 hours. Subsequently, a pH was adjusted to 9 by adding an aqueous ammonia solution, followed by stirring for an additional 10 hours and sonication for 2 hours.

Then, the stirred slurry was dried in an oven at 90° C., and dried powders were calcined at 450° C. for 4 hours under an argon atmosphere with a heating rate of 5° C./min. Finally, a negative active material in the form of a CNR@Si/BiSe core-shell composite having a porous structure was manufactured.

### Manufacture of Electrode (Half-Cell)

A negative electrode was manufactured using the manufactured CNR@Si/BiSe composite as an active material. A negative electrode slurry was obtained by mixing the CNR@Si/BiSe composite, a conductive agent (Super P), and a binder (PVDF) with each other in a weight ratio of 85:10:5. A viscosity of this mixture was adjusted using N-methyl-2-pyrrolidone (NMP) to make this mixture a slurry, and the slurry was applied to a copper foil current collector at a thickness of 200 μm.

After the slurry is applied, the electrode was dried in an oven at 100° C. for 12 hours and then pressed to a predetermined thickness at 150° C. under a pressure of 4,000 psi through a hot press process. Subsequently, electrode density was improved using a roll-press.

The manufactured electrode was assembled in a half-cell form in an argon glovebox using lithium metal as a counter electrode and using a polypropylene (PP) separator and an EC/DMC electrolyte (1 M LiPF₆). Electrochemical properties were evaluated using a WBCS-3000 battery cycler (Won A Tech), and measurements of cycle performance and rate capability, and impedance analyses were performed.

### <Physical Property Evaluation>

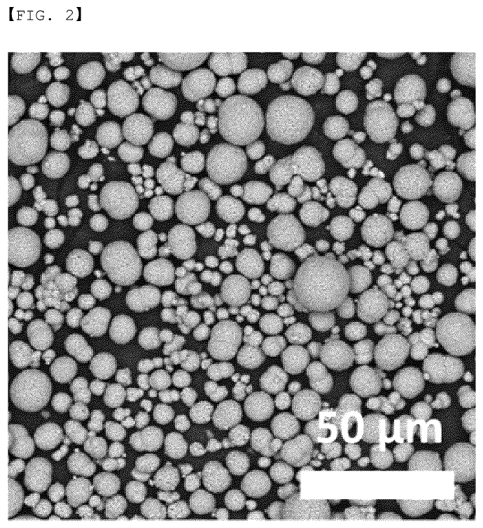

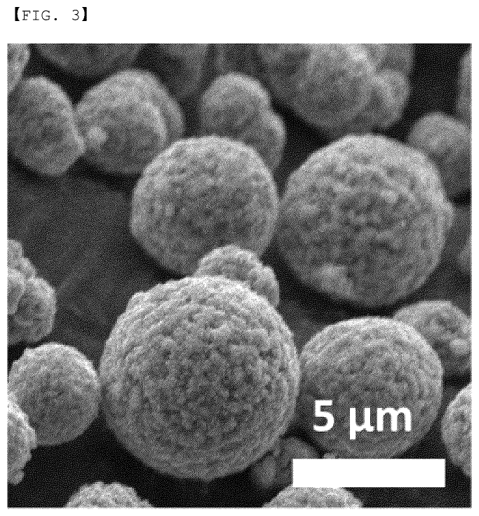

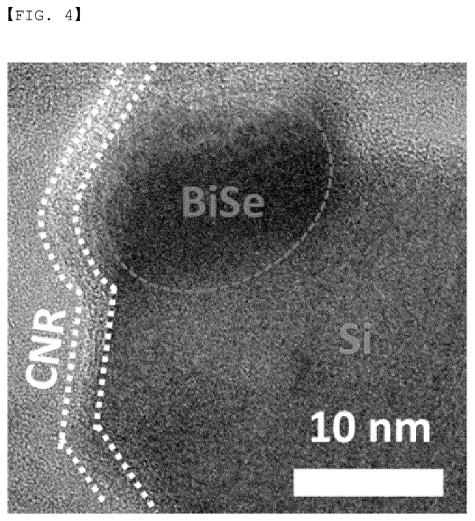

FIGS. 2 and 3 are field emission scanning electron microscope (FE-SEM) images showing a negative active material including the composite manufactured according to an embodiment of the present disclosure, and FIG. 4 is a high-resolution transmission electron microscope (HR-TEM) image showing a negative active material including the composite manufactured according to an embodiment of the present disclosure.

Referring to FIGS. 2 to 4, FE-SEM analysis was performed to examine the microstructure of the manufactured CNR@Si/BiSe core-shell composite. As a result, it can be confirmed that the composite included silicon-based microparticles with a size of about 5 μm.

By controlling the pyrolysis conditions of the BiSe precursor, a quaternary CNR@Si/BiSe nanocomposite with a core-shell structure containing carbon nanoribbons (CNR), silicon (Si), bismuth (Bi), and selenium (Se) was synthesized. The nanocomposite was formed in uniform spherical particle form.

Analysis results showed that the BiSe precursor retained its single-crystal structure even after synthesis and the internal core of the composite included BiSe nanocrystals with an average size less than 10 nm and porous silicon particles.

The core was encapsulated from the outside by a single-crystalline CNR layer with a thickness of about 2 nm to form a core-shell structure, and the shell included single-crystal carbon nanoribbons uniformly coating an outer surface of the composite.

It is considered that this core-shell structure was naturally formed during the pyrolysis process due to stress differences resulting from differences in thermal shrinkage among the individual components of the porous structure.

Meanwhile, in the Six-based composite identified as a control, no single-crystal structure was observed. On the other hand, the BiSe component in the CNR@Si/BiSe core-shell composite according to the present disclosure retained its unique pure single-crystal phase. Therefore, it was confirmed that excellent crystallinity and structural stability were achieved.

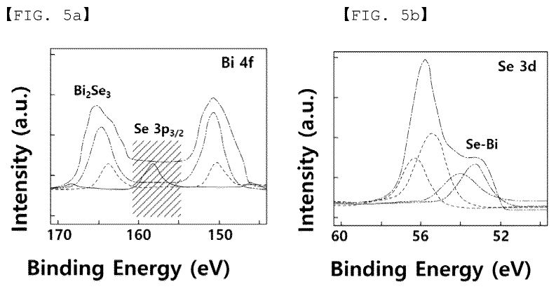

FIGS. 5a and 5b are graphs showing the results of X-ray photoelectron spectroscopy (XPS) for analyzing a surface chemical composition of the composite according an embodiment of the present disclosure. FIG. 5a is an XPS graph showing the Bi 4f binding energy of the composite according to an embodiment of the present disclosure, and FIG. 5b is an XPS graph showing the Se 3d binding energy of the composite according to an embodiment of the present disclosure.

Referring to FIG. 5a, in a core-level scan of the Bi 4f region performed in the binding energy in the range of 155 to 170 eV, two major peaks centered at approximately 166.08 eV and 151.06 eV were identified, which are spin-orbit coupling peaks corresponding to 4f_{5/2} and 4f_{7/2}, respectively. The binding-energy difference between the two peaks was identified to be about 5 eV, which is consistent with the characteristic peak spacing for Bi₂Se₃ crystal phase formation.

The spectrum was precisely analyzed using a Lorentzian-Gaussian fitting function, and the 4f_{5/2} and 4f_{7/2} peaks were deconvoluted into three peaks corresponding to Bi⁵⁺, Bi³⁺, and Bi³⁺ (Bi—Se) oxidation states, respectively. Among these, the Bi⁵⁺ and Bi³⁺ peaks with relatively high binding energies suggest the presence of Bi—O bonds, which are considered to be due to partial oxidation of Bi₂Se₃.

Referring to FIG. 5b, in the core spectrum of the Se 3d region measured in the binding energy in the range of 50 to 60 eV, an asymmetric main peak was observed, and the peak was also deconvolved using a Lorentzian-Gaussian fitting function. As a result, two peaks corresponding to Se 3d_{3/2} and Se 3d_{5/2} were obtained, of which the 3d_{5/2} peak attributed to Se—Se bonding was clearly identified.

Through these analytical results, it was confirmed that the synthesized CNR@Si/BiSe core-shell composite exhibited the formation of the Bi₂Se₃ phase and single crystallinity, as well as the coexistence of various binding states such as Bi—Se, Bi—O, and Se—Se, which are considered to significantly influence the electronic structure and reactivity of the composite.

Furthermore, the present composite was confirmed to have a structure capable of ensuring both excellent electrochemical performance and structural stability by providing abundant active sites (Li⁺ storage active sites) for enhancing lithium-ion storage capability and facilitating efficient electron transport through a defect-suppressed Li⁺ insertion layer and a uniform outer carbon nanoribbon shell structure.

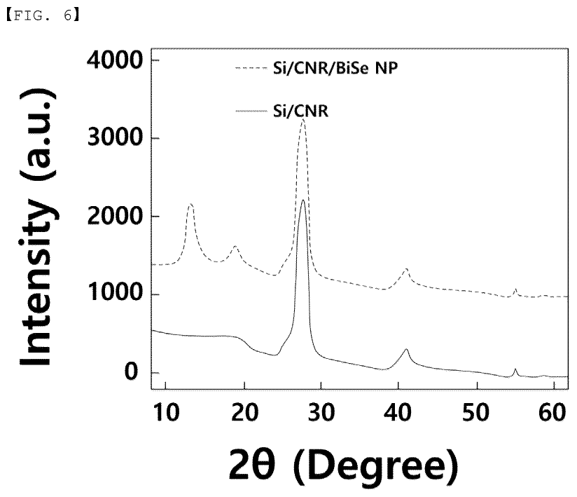

FIG. 6 shows the results of an X-ray diffraction (XRD) pattern for analyzing a crystal structure of the composite according to an embodiment of the present disclosure. In this embodiment, X-ray diffraction (XRD) analysis was performed to analyze the crystal structures of the manufactured composite and raw material. The measurements were performed in the 2θ range of 20 to 80° with a step size of 0.02° and a step time of 2 s, under an acceleration voltage of 40 kV and a current of 100 mA.

Referring to FIG. 6, in the CNR/Si composite, a diffraction peak corresponding to the (002) plane was observed at 2θ=28.17°, which was identified as a characteristic peak originating from silicon crystal phase. Meanwhile, no peaks corresponding to the silicon oxide (SiOₓ) phase were observed, which is attributed to SiOₓ generally having an amorphous structure and thus not exhibiting distinct crystalline peaks in XRD.

In addition, in XRD results of the CNR@Si/BiSe core-shell composite, three prominent diffraction peaks of an anatase crystal phase based on a core structure including BiSe and silicon clearly appeared, which may demonstrate that other crystal or impurity phases do not exist in the present composite.

The main peaks of the composite reflect a structure in which Si/BiSe-based core particles are uniformly encapsulated by an outer carbon layer (CNR shell). In particular, the intensity of the diffraction peak by carbon (C) in the present composite weaker than that of silicon (Si), so that primarily only the diffraction peak corresponding mainly to silicon was clearly observed in an XRD pattern.

These XRD analysis results indicate that the CNR@Si/BiSe core-shell composite according to the present disclosure was uniformly synthesized, without impurities, while maintaining high crystallinity, and the interfaces among the silicon, BiSe, and carbon components were stably formed.

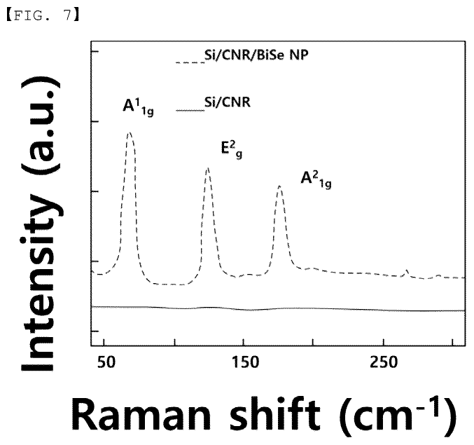

FIG. 7 shows the results of Raman spectroscopy analysis to confirm the structural characteristics of the composite according to an embodiment of the present disclosure.

Referring to FIG. 7, Raman analysis was performed at room temperature, with Si/CNR composites and Si/CNR/BiSe NP composites used as comparative samples, respectively. The excitation light source used for the analysis had a wavelength of 514 nm (photon energy: 2.4 eV), and the spectral resolution and the diffraction grating were set at 0.5 cm⁻¹ and 2,400 I/mm, respectively. The laser power was maintained below 3 mW to prevent thermal damage to the samples.

As a result of the analysis, the characteristic Raman-active vibrational modes of Bi₂Se₃, namely A₁g¹, E_g², and A₁g², were clearly observed in the spectral range of 50 to 300 cm⁻¹. These vibrational modes in the Si/CNR/BiSe composite were measured at peak positions of 71.664 cm⁻¹ (A₁g¹), 132.185 cm⁻¹ (E_g²), and 174.207 cm⁻¹ (A₁g²), respectively, indicating that the unique crystal structure of Bi₂Se₃ was maintained.

Furthermore, in the Si/CNR/BiSe NP composite with BiSe introduced, a simultaneous change in overall peak intensity and position was observed compared to the Si/CNR composite. This change means that a vibrational mode in a crystal lattice was adjusted due to the introduction of BiSe, and is interpreted as a result of reflecting the structural integrity and a change in electronic structure of the CNR@Si/BiSe composite.

The Raman analysis results indicate that the Bi₂Se₃ single-crystal phase is stably formed in the core-shell composite according to the present disclosure, and chemical bonding and structural interactions among the components in the composite are effectively implemented.

### <Electrochemical Analysis>

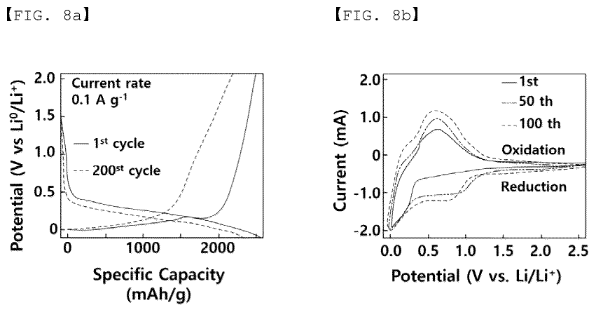

FIG. 8a shows the charge and discharge curves of a battery using the composite according to an embodiment of the present disclosure, and FIG. 8b shows the results of cyclic voltammetry (CV) analysis of a battery using the composite according to an embodiment of the present disclosure.

Referring to FIG. 8a, it was confirmed that according to the results measured at a 0.1 C-rate, the composite exhibited discharge and charge capacities of 2,254 mAh/g and 2,514 mAh/g, respectively, and high capacity retention was maintained even at a 0.5 C-rate. This result is considered to be due to the significant improvement of electrochemical reactivity caused by the unique structural characteristics of the CNR@Si/BiSe core-shell composite according to the present disclosure, that is, an increase in specific surface area and improvement of structural stability.

In particular, it is interpreted that the high-capacity characteristics of the silicon-based electrode were well manifested, as an alloying reaction between silicon and lithium (Li—Si alloying) actively proceeded during the charge and discharge reactions. In addition, the BiSe topological nanocrystal structure effectively buffered the volume expansion of silicon to prevent structural collapse. The carbon nanoribbon (CNR) matrix formed conductive paths while simultaneously suppressing the aggregation of silicon particles.

Moreover, the porous structure of the composite increased the internal surface area and shortened the diffusion paths of Li⁺, thereby enabling rapid ion transport. Consequently, it was confirmed that the CNR@Si/BiSe composite-based negative electrode exhibited excellent electrochemical performance, particularly in terms of high capacity, structural stability, and lithium diffusion kinetics.

Referring to FIG. 8b, the CV measurements were performed in the potential window of 0.01 V to 3.0 V, allowing qualitative analysis of the electrochemical reaction characteristics occurring in the electrode.

An oxidation peak was observed around 0.58 V in the CV curve, and this peak showed a gradual decreasing trend with repeated cycling. This suggests that the stabilization of solid electrolyte interphase (SEI) formation was achieved as a result of the surface modification of the electrode, thereby improving the electrochemical stability.

In addition, in the first discharge curve, two reduction peaks were observed near 0.35 V and 1.1 V, indicating the effective formation of an SEI layer due to the large contact area on the electrode surface. This stable formation of the SEI contributes to the improvement of the initial cycle efficiency and the maintenance of a long lifespan of the battery.

Thus, the CNR@Si/BiSe core-shell composite is evaluated as an effective negative electrode material structure capable of maximizing the high-capacity characteristics of silicon while securing excellent charge and discharge characteristics and electrochemical reactivity owing to the structural and electrochemical stability provided by BiSe and CNR.

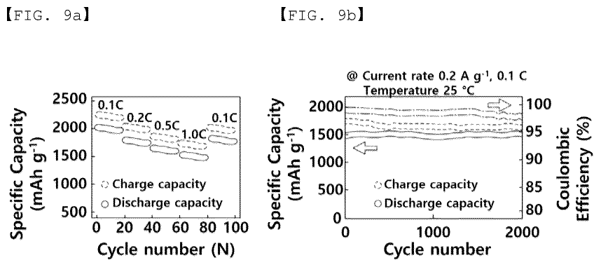

FIG. 9a shows the rate capability of a battery using the composite according to an embodiment of the present disclosure, and FIG. 9b shows the cycle life and coulombic efficiency of a battery using the composite according to an embodiment of the present disclosure, respectively.

Referring to FIG. 9a, the CNR@Si/BiSe composite-based battery exhibited a high capacity retention of 98.5% or more after 100 or more cycles of repeated charge and discharge at various current conditions, including 0.1, 0.2, 0.5, and 1 C-rates. In addition, even at 0.5, 1.0, and 2.0 C-rates, the cell maintained relatively high capacity characteristics compared to cells using conventional silicon/graphite negative electrode materials.

In particular, at a 0.5 C-rate, a cycle stability of 99% or more was achieved, indicating that a composite of the core-shell structure according to the present disclosure effectively suppresses capacity loss caused by increased lithium diffusion resistance. This is interpreted as a result of the surface of the Si/BiSe core particles being uniformly modified by CNR, leading to the stable formation of the SEI layer. As a result, it can be seen that effects such as reduced electrode-electrolyte interfacial resistance, reaction homogenization, and improved capacity retention were observed.

Referring to FIG. 9b, the long cycle performance of the battery was evaluated at a current density of 1 A/g, and the results showed a capacity retention of 98% or more even after 2,000 cycles. The irreversible capacity at this condition was measured to be about 1,984 mAh/g, suggesting excellent lithium storage efficiency and structural stability within the composite structure.

Furthermore, even under a high current density of 5 A/g, the battery maintained a reversible capacity of about 1,950 mAh/g or more, and the coulombic efficiency was stably maintained at about 98% even after cycling.

These results indicate CNR@Si/BiSe core-shell composite structure maintains electrochemical reactivity even under high-rate charge and discharge conditions and provides a smooth movement path for lithium ions and electrons, thereby satisfying both long lifespan and high-rate charge and discharge characteristics.

The negative active material according to an embodiment of the present disclosure exhibits excellent electrochemical performance and structural stability by including a silicon-based active material composite including a silicon-based active material, topological material nanoparticles, and a carbon nanoribbon.

The negative active material according to an embodiment of the present disclosure has high capacity by including a silicon-based active material and has excellent cycle characteristics due to structural stability.

The negative active material according to an embodiment of the present disclosure provides high electrical conductivity by including a silicon-based active material core and a shell formed on a surface of the core and including a nanoribbon.

As described above, embodiments disclosed have been described with reference to the attached drawings. A person having ordinary knowledge in the art to which the present disclosure pertains will understand that the present disclosure may be practiced in forms different from the embodiments disclosed herein without changing its technical spirit or essential features. The embodiments disclosed are merely illustrative and should not be construed as limiting.

### DESCRIPTION OF REFERENCE SIGNS

10: Composite
11: Core
12: Shell

What is claimed is:

1. A negative active material comprising: a composite including a silicon-based active material, topological material nanoparticles, and a carbon nanoribbon.

2. The negative active material of claim 1, wherein the composite includes a core including the silicon-based active material and the topological material nanoparticles, and a shell surrounding at least a portion of the core and including the carbon nanoribbon.

3. The negative active material of claim 2, wherein the topological material nanoparticles include at least one of BiSe and BiTe.

4. The negative active material of claim 3, wherein the topological material nanoparticles have an average particle diameter of 5 nm to 50 nm.

5. The negative active material of claim 2, wherein the silicon-based active material includes at least one of Si and SiOₓ (0<x≤2).

6. The negative active material of claim 5, wherein the silicon-based active material has an average particle diameter of 50 nm to 5 μm.

7. The negative active material of claim 6, wherein the silicon-based active material has a single-crystal structure.

8. The negative active material of claim 2, wherein the shell has a thickness of 5 nm to 50 nm.

9. The negative active material of claim 2, wherein the composite has a porous structure.

10. The negative active material of claim 9, wherein the composite has an average particle diameter of 50 nm to 5 μm.

11. A lithium secondary battery comprising:
a negative electrode including the negative active material of claim 1;
a positive electrode including a positive active material; and
an electrolyte transferring lithium ions to the positive electrode and the negative electrode.

12. The lithium secondary battery of claim 11, wherein the lithium secondary battery exhibits a capacity retention of 98% or more after 2,000 or more charge and discharge cycles at 0.1 C.

13. The lithium secondary battery of claim 11, wherein the lithium secondary battery exhibits a capacity of 1,950 mAh/g or more after 2,000 or more charge and discharge cycles at a current density of 1 A/g.

14. A method for manufacturing a negative active material, the method comprising:
a pretreating step of treating a silicon-based precursor to manufacture porous silicon particles; and
a composite manufacturing step of manufacturing a composite of a core-shell structure using the pretreated silicon-based particles, a topological material precursor, and a carbon nanoribbon precursor.

15. The method of claim 14, wherein the pretreating step includes:
melting a silicon-based precursor and the topological material precursor; and
condensing a porous composite, and
wherein the composite manufacturing step includes:
annealing the pretreated particles; and
forming a carbon nanoribbon shell outside the annealed particles.
